(19) United States
(12) Patent Application Publication
(10) Pub. No.: US 2008/0165486 A1
(43) Pub. Date: Jul. 10, 2008

(54) COMPUTER FRONT BEZEL

(75) Inventors: YUN-LUNG CHEN, Tu-Cheng (TW); YU-MING XIAO, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/759,246

(22) Filed: Jun. 7, 2007

(30) Foreign Application Priority Data
Jan. 5, 2007 (TW) 96200250

(51) Int. Cl. H05K 5/02

(52) U.S. Cl. 361/683; 312/223.2; 361/724

(57) ABSTRACT

A computer front bezel includes a bezel body (10), a holding member (30), a sliding member (80), and a resilient member (100). The bezel body defines an opening (138) therein. The holding member is pivotably secured on the bezel body for covering the opening of the bezel body when the holding member is in a closed position. The sliding member is secured on the bezel body. Engagement between the holding member and the sliding member blocks the holding member from being pivoted away from the closed position. The sliding member is capable of being pushed from outside of the bezel body to slide on the bezel body to release the holding member from the sliding member. The resilient member is secured on the bezel body for rotating the holding member to leave from the closed position when the holding member is released from the sliding member.

### BACKGROUND

1. Technical Field

The present invention relates to front bezels, and more particularly to a front bezel of a computer.

2. General Background

Today, portable hard disk drives are widely used to transfer large amounts of data from one computer to another. In use, the portable hard disk drive is usually placed outside of the computer, and connects to the computer with a data cable. At this time, the portable hard disk drive is in danger of being knocked to the ground.

What is needed, therefore, is a computer front bezel which is capable of securely receiving a portable device therein.

### SUMMARY

A computer front bezel includes a bezel body, a holding member, a sliding member, and a resilient member. The bezel body defines an opening therein. The holding member is pivotably secured on the bezel body for covering the opening of the bezel body when the holding member is in a closed position. The sliding member is secured on the bezel body. Engagement between the holding member and the sliding member blocks the holding member from being pivoted away from the closed position. The sliding member is capable of being pushed from outside of the bezel body to slide on the bezel body to release the holding member from the sliding member. The resilient member is secured on the bezel body for rotating the holding member to move from the closed position when the holding member is released from the sliding member.

Other advantages and novel features will be drawn from the following detailed description of preferred embodiments with attached drawings, in which:

### BRIEF DESCRIPTION OF THE DRAWINGS

FIG. 1 is an exploded, isometric view of a computer front bezel in accordance with a preferred embodiment of the present invention, the computer front bezel including a bezel body, a mounting member, a holding member, a torsion spring, a damping member, a sliding member, an operating member, and an elongated member;

FIG. 2 is similar to FIG. 1, but viewed from another aspect; and

FIG. 3 is another isometric view of the bezel body of FIG. 1;

FIG. 4 is similar to FIG. 3, but viewed from another aspect;

FIG. 5 is another isometric view of the holding member of FIG. 1;

FIG. 6 is an assembled view of the bezel body, the sliding member, the operating member, and the elongated spring of FIG. 1;

FIG. 7 is similar to FIG. 6, but viewed from another aspect;

FIG. 8 is an assembled view of FIG. 1, showing the holding member in a closed position; and

FIG. 9 is similar to FIG. 8, but viewed from another aspect and showing the holding member in an open position.

### DETAILED DESCRIPTION OF PREFERRED EMBODIMENTS

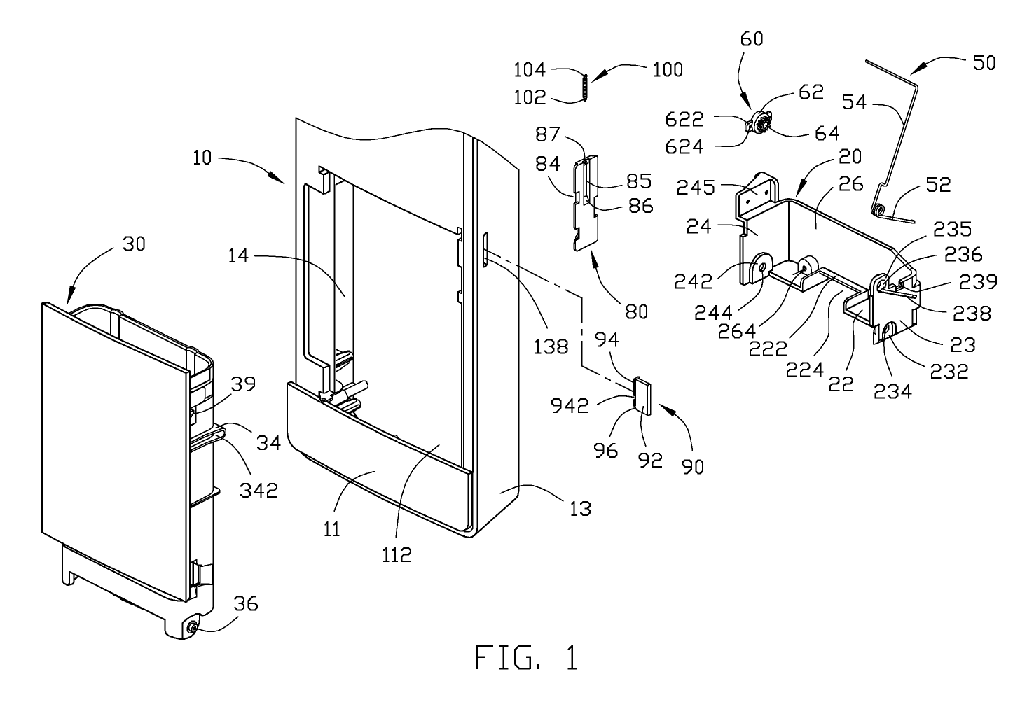

Referring to FIG. 1, a computer front bezel in accordance with an embodiment of the present invention comprises a bezel body 10, a mounting member 20, a holding member 30, a torsion spring 50, a damping member 60, a sliding member 80, an operating member 90, and an elongated member 100.

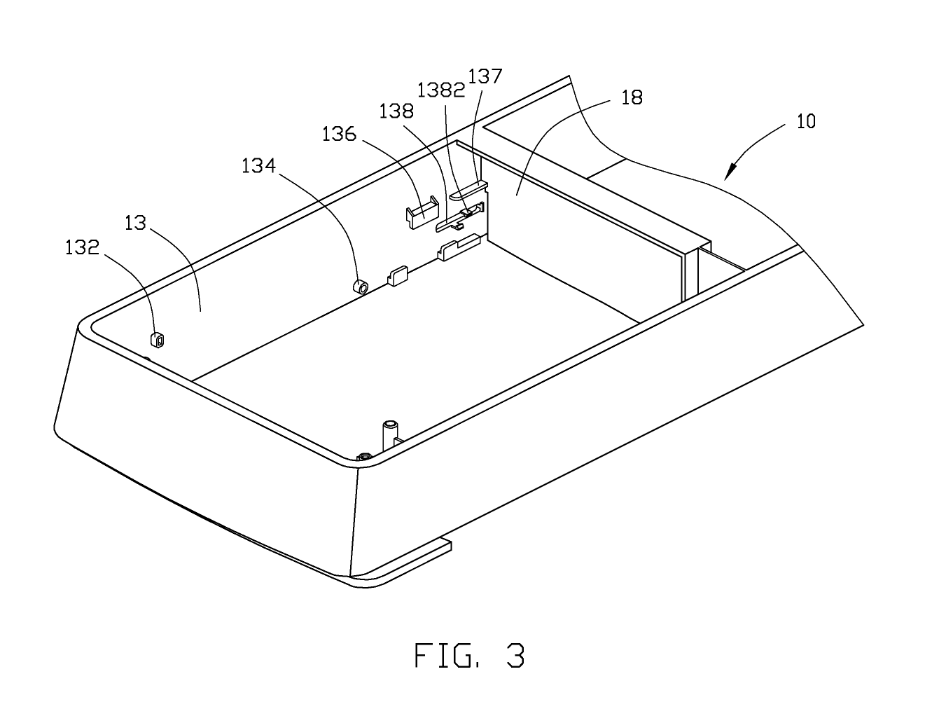

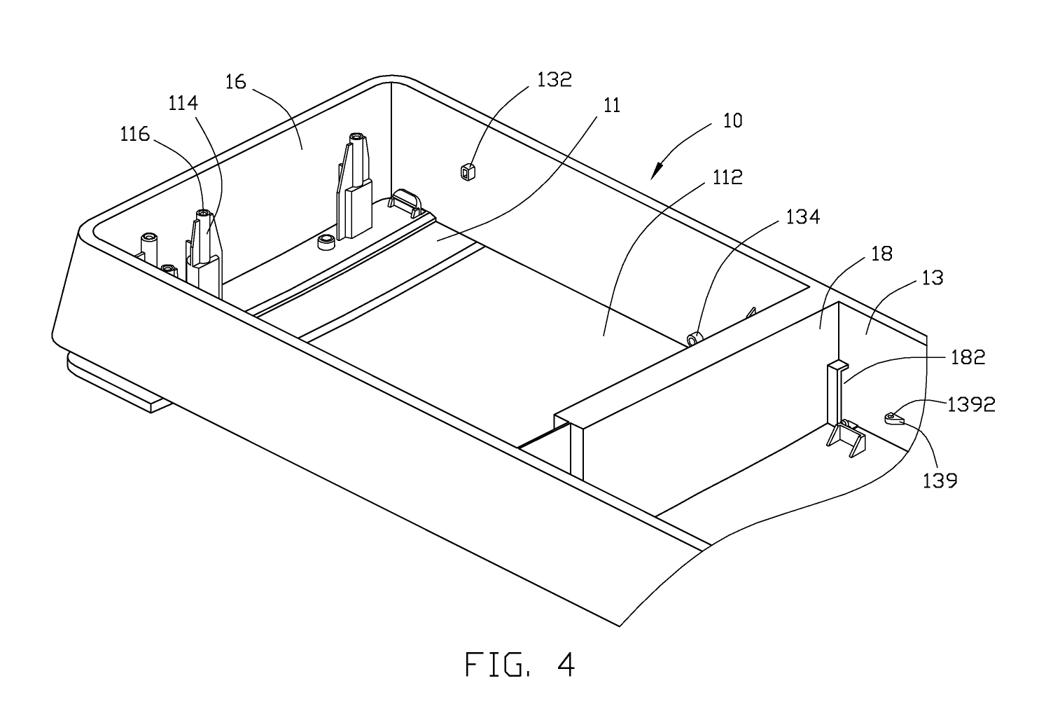

Referring to FIGS. 1-4, the bezel body includes a front wall 11, two opposite side walls 13, 14 and a bottom wall 16 respectively formed on adjacent edges of the front wall 11. The bottom wall 16 and the side walls 13, 14 are generally perpendicular to the front wall 11. An internal wall 18 is formed between the side walls 13, 14, parallel and opposite to the bottom wall 16. An opening 112 is defined in the front wall 11 between the bottom wall 16 and the internal wall 18. Two mounting posts 114, each defining a mounting hole 116 therein, are formed on an inner surface of the front wall 11 adjacent the bottom wall 16. A positioning block 132 protrudes from an inner surface of the side wall 13 adjacent the bottom wall 16. A positioning post 134, a plurality of guiding blocks 136 with L-sections, and a projecting tab 137 are formed on the inner surface of the side wall 13 below the internal wall 18. A through hole 138 is defined in the side wall 13 between the projecting tab 137 and one of the guiding blocks 136 opposite to the projecting tab 137. Two resilient hooks 1382 are formed on the inner surface of the side wall 13 at two opposite edges of the through hole 138 respectively. A securing tab 139 with a securing hole 1392 (shown in FIG. 4) defined therein protrudes from the inner surface of the side wall 13 above the internal wall 18. A guiding opening 182 (shown in FIG. 4) is defined in the internal wall 18, adjacent the guiding blocks 136.

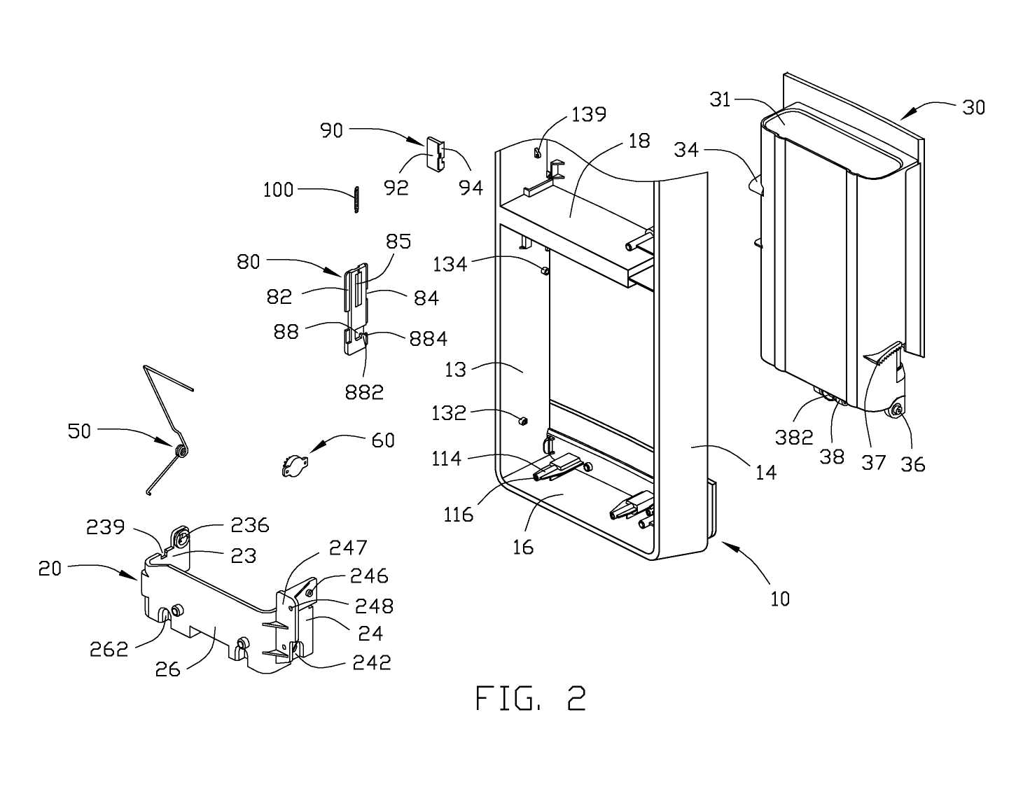

Referring to FIGS. 1-2, a mounting member 20 includes a bottom wall 22, two opposite parallel side walls 23, 24, and a rear wall 26 perpendicular to the side walls 23, 24. The side walls 23, 24, and the rear wall 26 are perpendicular to the bottom wall 22. A protruding portion 222 is formed on an inner surface of the bottom wall 22. An opening 224 is defined in the protruding portion 222. A protrusion 232, 242 adjacent the bottom wall 22 with a pivot hole 234, 244 defined therein protrudes from an inner surface of each of the side walls 23, 24. Each of the protrusions 232, 242 defines a pivot hole 234, 344 therein. A projecting portion 235 with a through hole 236 defined therein extends from a top edge of the side wall 23. A slanted elongate slot 238 is defined in an outer surface of the side wall 23 and connects with the through hole 236. A cutout 239 is defined in the side wall 23 adjacent the projecting portion 235 above the slot 238. A bent portion 245 is formed on a top edge of the side wall 24. Two mounting holes 246 are defined in the bent portion 245. A vertical wall 247 protrudes perpendicularly from an outer surface of the side wall 24 and the bent portion 245. A securing hole 248 is defined in the vertical wall 247. Two protrusions 262 (shown in FIG. 1) are formed on an inner surface of the rear wall 26. Each protrusion 262 defines a through hole 264 therein.

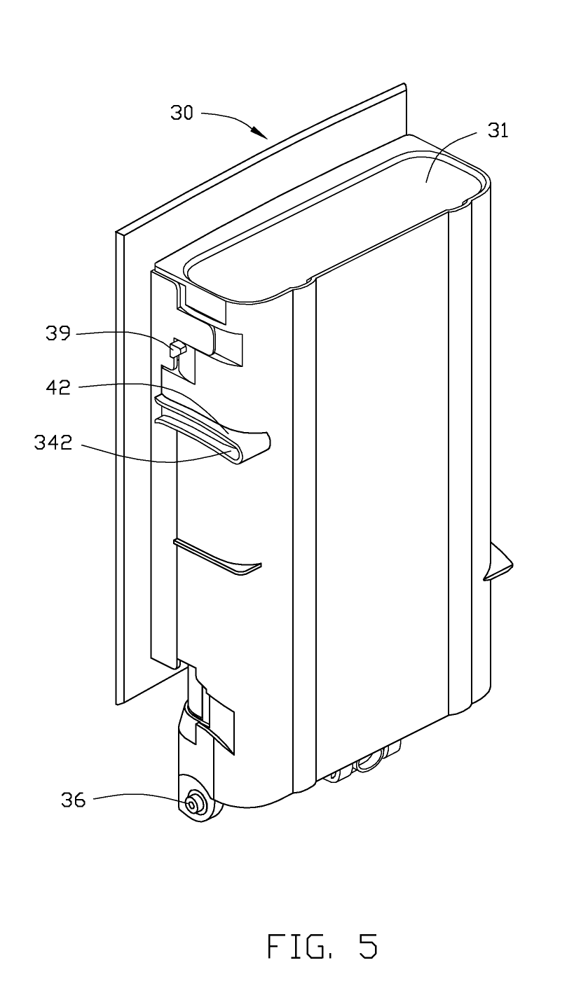

Referring to FIGS. 1, 2, and 5, a holding member 30 has a holding space 31 to receive a portable hard disk drive (not shown) therein. A locking tab 39 and a protrusion 34 are formed at a top portion of a side surface of the holding member 30, adjacent the side wall 13 after the holding member 30 is secured on the bezel body 10. A guiding slot 342 is defined in the protrusion 34 for the positioning post 134 of the bezel body 10 sliding therein. An arc-shaped toothed portion 37 is formed on a bottom portion of another opposite side surface of the bezel body 10. A pair of pivot posts 36 is formed at two bottom ends of the side surfaces of the bezel body 10 respectively. A connecting portion 38 is formed on a bottom end of the bezel body 10. A connecting hole 382 is defined in the connecting portion 38 communicating with the holding space 31 for cables inserting therethrough.

Referring to FIG. 1, a torsion spring 50 is provided for being received in the through hole 236 of the projecting portion 235 of the mounting member 20, and has two arms 52, 54.

Referring to FIG. 1, a damping member 60 includes a mounting portion 62 and a pinion 64 rotatably secured on the mounting portion 62. Two ear portions 622 extend from opposite sides of the mounting portion 62, and respectively define a mounting hole 624 therein corresponding to the mounting hole 246 of the bent portion 245 of the mounting member 20. The pinion 64 is capable of being rotated when a more than a predetermined force is exerted thereon.

Referring to FIGS. 1-2, a rectangular sliding member 80 has two rims 82 respectively located at opposite edges to have the sliding member 80 slidable between the guiding blocks 136 of the bezel body 10. A plurality of cutouts 84 is defined in the rims 82 for allowing the sliding member 80 to be capable of being secured between the guiding blocks 136 of the bezel body 10. A rectangular through slot 85 is defined in the sliding member 80. A locking hole 87 is defined in the sliding member 80 near a side of the through slot 85, and a slanted surface 86 is formed on an edge bordering the through slot 85 opposite to the locking hole 87. A latch slot 88 is defined in a surface of the sliding member 80 for receiving the locking tab 39 of the holding member 30. A blocking tab 882 is formed at an edge of an exit of the latch slot 88. The blocking tab 882 has a slanted surface 884 formed thereon, for engaging with the slanted surface of the locking tab 39.

Referring to FIGS. 1-2, an operating member 90 is provided to be received in the through slot 85. The operating member 90 includes a pushing portion 92 and a base portion 94 perpendicular to the pushing portion 92. Two cutouts 942 are defined in opposite edges of the base portion 94 respectively, for the hooks 1382 of the bezel body 10 being inserted therethrough.

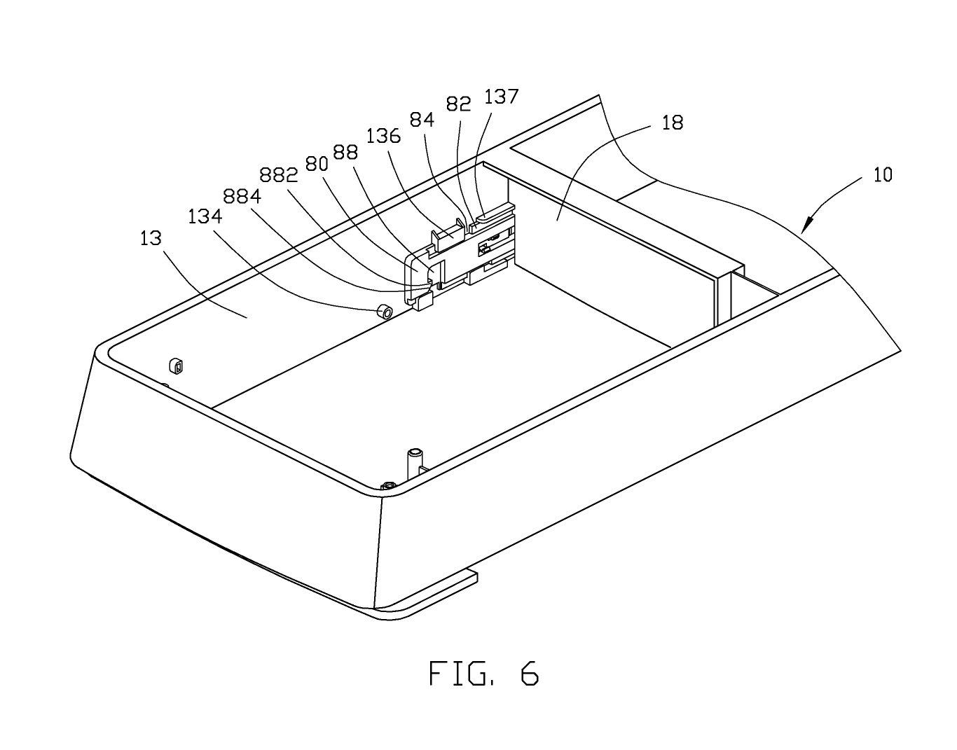

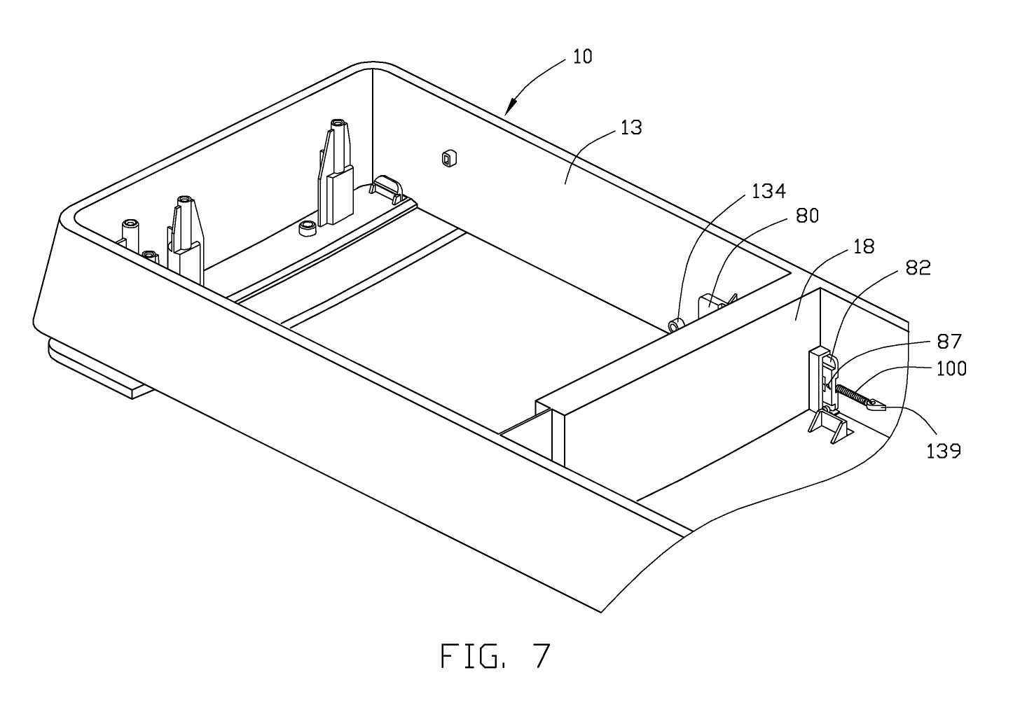

Referring also to FIGS. 6-7, the pushing portion 92 of the operating member 90 is inserted into the through hole 138 of the bezel body 10 from inside of the side wall 13, and extends outside of the side wall 13. The base portion 94 abuts on the inner surface of the side wall 13, thereby blocking the operating member 90 moving from the side wall 13 through the through hole 138. The hooks 1382 of the bezel body 10 sandwich the base portion 94 of the operating member 90 therebetween via engaging with the cutouts 942 of the base portion 94. The guiding blocks 136 of the bezel body 10 engage in the cutouts 84 of the sliding member 80. The sliding member 80 is pushed to slide along the side wall 13 and insert into the guiding opening 182 of the internal wall 18, and the rims 82 of the sliding member 80 are slidably positioned between a portion of each guiding block 136 and the inner surface of the side wall 13. A hook end 102 of an elongated spring 100 is engaged in the locking hole 87 of the sliding member 80, another hook end 104 is engaged in the securing hole 1392 of the securing tab 139 of the side wall 13. The spring 100 has a first length. The base portion 94 of the operating member 90 is slidably received in the slot 85 of the sliding member 80 and the slanted surface 96 of the base portion 94 engages with the slanted surface 86 of the sliding member 80, thereby urging the base portion 94 of the operating member 90 to abut on the inner surface of the side wall 13.

When the pushing portion 92 of the operating member 90 is pushed from outside of the side wall 13 to slide into the through hole 138 in a first direction perpendicular to the side wall 13, the operating member 90 urges the sliding member 80 to slide along the inner surface of the side wall 13 toward the bottom wall 16 in a second direction perpendicular to the first direction by engagement between the slanted surface 96 of the base portion 94 of the operating member 90 and the slanted surface 86 of the sliding member 80. The spring 100 is thereby elongated to a second length, which is greater than the first length. When the pushing portion 92 of the operating member 90 is released, the spring 100 rebounds from the second length to the first length so as to pull the sliding member 80 to slide reverse to the second direction. Due to the engagement between the slanted surface 96 of the base portion 94 of the operating member 90 and the slanted surface 86 of the sliding member 80, the sliding member 80 therefore urges the operating member 90 to slide reverse to the first direction to its original position. The pushing portion 92 of the operating member 90 thus extends out of the bezel body 10 again.

Referring also to FIGS. 1, 2, and 9, the torsion spring 50 is received in the through hole of the mounting member 20. The arm 52 is inserted through the hole 236 and located in the elongate slot 238 of the side wall 23, and the arm 54 is positioned adjacent the rear wall 26 of the mounting member 20. The damping member 60 is mounted on an inner surface of the bent portion 245 of the mounting member 20 by two locking members (not shown), such as screws, extending into the mounting holes 624 of the damping member 60 and the corresponding mounting hole of the bent portion 245. The mounting member 20 is then secured on the bezel body 10 between the sidewalls 13, 14 and adjacent the bottom wall 16, by two locking members (not shown), such as screws, extending into the through holes 264 of the protrusions 262 of the mounting member 20 and the corresponding mounting holes 116 of the mounting posts 114 of the bezel body 10. The positioning block 132 of the side wall 13 is inserted into the cutout 239 of the mounting member 20. The bottom end of the holding member 30 is inserted through the opening 12 of the bezel body 10 and received in a space between the walls 23, 24, and 26 of the mounting member 20. The holding member 30 is pivotably secured on the bezel body 10 by the pivot posts 36 thereof pivotably inserting into the corresponding pivot holes 234, 244 of the mounting member 20. The positioning post 134 of the side wall 13 of the bezel body 10 is slidably positioned in the guiding slot 342 of the holding member 30. The toothed portion 37 of the holding member 30 engages with the pinion 64 of the damping member 60. The arm 54 of the torsion spring 50 abuts on an outer surface of the holding member 30.

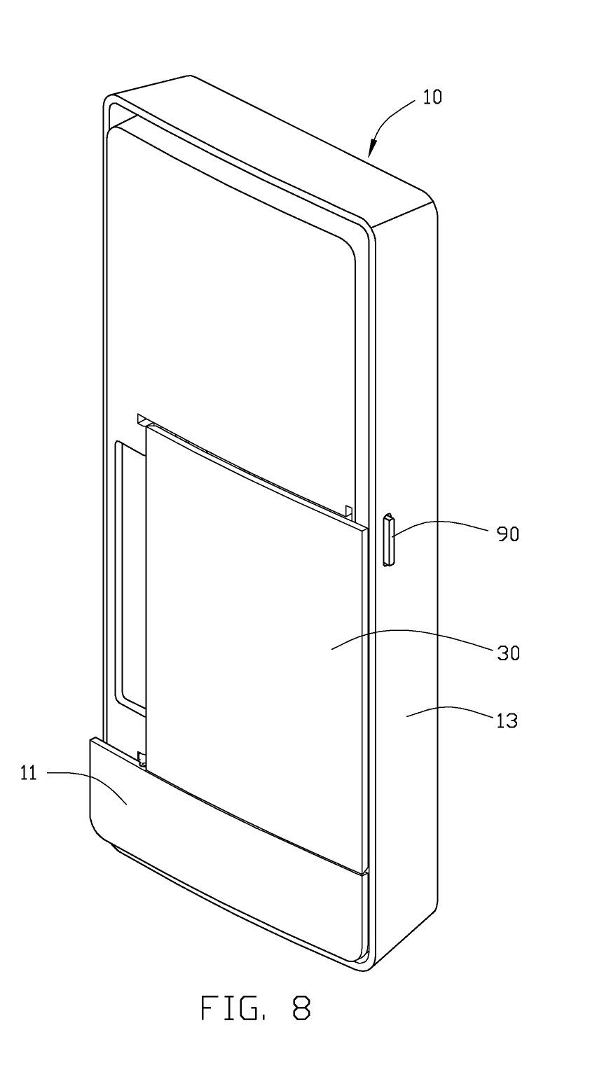

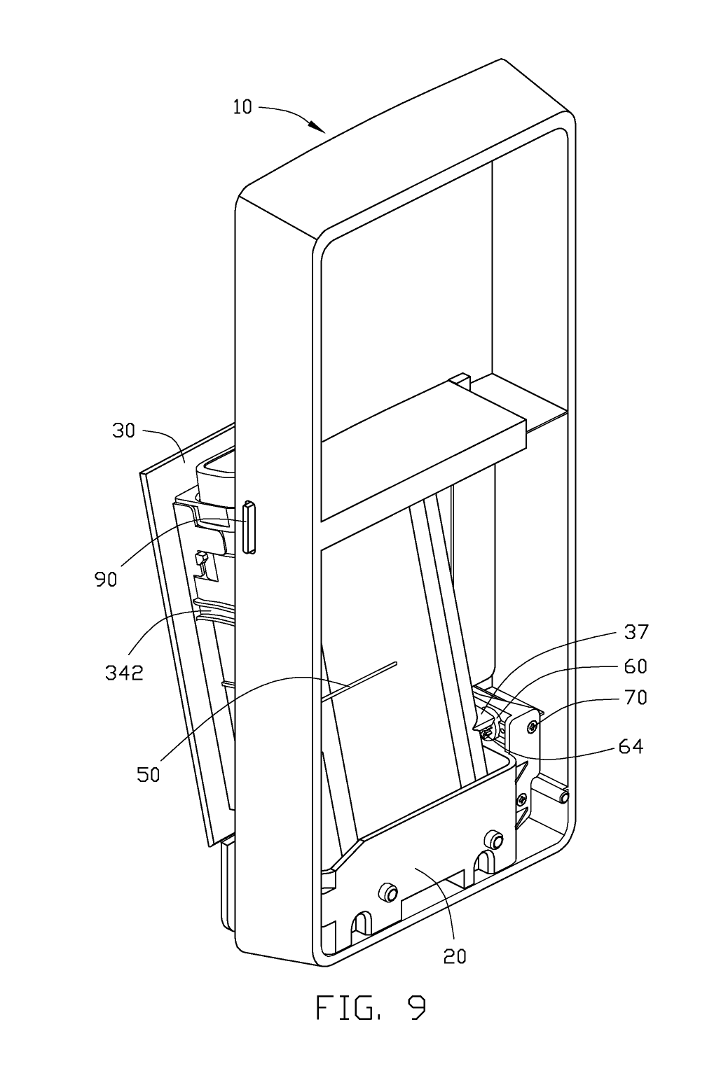

Referring also to FIGS. 8-9, the holding member 30 has an open position, in which the opening 112 of the bezel body 10 is exposed and the torsion spring 50 has an original state, and a closed position, in which the opening 12 of the bezel body 10 is covered by the holding member 30 and the torsion spring 50 is resiliently deformed. When the holding member 30 is rotated from the open position to the closed position to cover the opening 112, the holding member 30 resiliently deforms the torsion spring 50 and urges the pinion 64 of the damping member 60 to rotate. The locking tab 39 of the holding member 30 pushes the blocking tab 882 to slide the sliding member 80 in the second direction by engagement between the slanted surface of the locking tab 39 and the slanted surface 884 of the blocking tab 882. The spring 50 is extended from the first length to the second length. When the locking tab 39 slides past the blocking tab 882 of the sliding member 30, the spring 50 rebounds to the first length to slide the sliding member 50 reverse to the second direction and engage the locking tab 39 with the blocking tab 882. The holding member 30 is thus stably positioned in the closed position. When the pushing portion 92 of the operating member 90 is pushed inward to slide the sliding member 80 in the second direction and release the locking tab 39 from the blocking tab 882 of the latch slot 88, the torsion spring 50 rebounds to urge the holding member 30 to rotate from the closed position to the open position.

In use, the portable hard disk drive or other portable devices can be inserted and stored in the holding space 31 when the holding member 30 is rotated out to the open position, and secured in the bezel body 10 when the holding member 30 is rotated from the open position to the closed position.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A computer front bezel, comprising:
a bezel body defining an opening therein;
a holding member secured on the bezel body and capable of being pivoted from an open position in which the holding member is rotated out from the opening of the bezel body, to a closed position in which the holding member covers the opening of the bezel body, a locking tab being formed on the holding member;
a sliding member slidably secured on the bezel body, a blocking tab being formed on the sliding member for engaging with the locking tab to block the holding member being pivoted from the closed position to the open position;
a first resilient member connected between the bezel body and the sliding member for maintaining engagement between the blocking tab of the sliding member and the locking tab of the holding member; and
an operating member secured on the bezel body configured for sliding the sliding member along the bezel body to cause the blocking tab release the locking tab.

2. The computer front bezel as described in claim 1, wherein the bezel body defines a through hole therein, the operating member comprising a pushing portion slidably received in the through hole of the bezel body.

3. The computer front bezel as described in claim 2, wherein the operating member further comprises a base portion perpendicular to the pushing portion, the base portion being blocked by edges of the through hole of the bezel body to prevent the operating member sliding out from the through hole.

4. The computer front bezel as described in claim 3, wherein the base portion of the operating member has a slanted surface formed thereon, the sliding member defining a slot therein for receiving the base portion of the operating member, a slanted surface being formed on an edge of the through slot for engaging with the slanted surface of the operating member such that when the operating member is pushed in a first direction, the slanted surface of the operating meber urges the slanted surface of the sliding member to slide the sliding member in a second direction perpendicular to the first direction.

5. The computer front bezel as described in claim 1, wherein a securing tab with a securing hole defined therein is formed on the bezel body, the sliding member defining a locking hole therein, ends of the first resilient member are engaged in the securing hole of the securing tab and the locking hole of the sliding member respectively.

6. The computer front bezel as described in claim 1, wherein a plurality of guiding blocks is formed on the bezel body, two rims being formed on opposite edges of the sliding member respectively, and slidably positioned between portions of the guiding blocks and the bezel body.

7. The computer front bezel as described in claim 1, wherein a second resilient member is secured on the bezel body for pivoting the sliding member from the closed position to the open position when the blocking tab releases the locking tab.

8. The computer front bezel as described in claim 1, wherein a damping member having a rotatable pinion is secured on the bezel body, an arc toothed portion being formed on the holding member and meshed with the pinion of the damping member for stable pivoting of the holding member.

9. The computer front bezel as described in claim 1, wherein the holding member defines a space configured for receiving a portable hard disk drive therein, the space being accessible from outside of the bezel body at the open position and being unaccessible from outside of the bezel body at the closed position.

10. The computer front bezel as described in claim 1, wherein a positioning post is formed on the bezel body, the holding member defining a guiding slot therein for the positioning post sliding therein, an edge of the guiding slot engaging with the positioning post when the holding member is pivoted to the open position.

11. A computer front bezel, comprising:
a bezel body defining an opening therein;
a holding member pivotably secured on the bezel body for covering the opening of the bezel body when the holding member is in a closed position;
a sliding member secured on the bezel body, engagement between the holding member and the sliding member blocking the holding member from being pivoted away from the closed position, the sliding member being capable of being pushed from outside of the bezel body to slide along the bezel body to disengage the holding member from the sliding member; and
a resilient member secured on the bezel body for rotating the holding member to leave from the closed position when the holding member is released from the sliding member.

12. The computer front bezel as described in claim 11, wherein a locking tab is formed on the holding member, a blocking tab being formed on the sliding member for engaging with the locking tab of the holding member to maintain the holding member in the closed position.

13. The computer front bezel as described in claim 12, wherein another resilient member is connected between the bezel body and the sliding member for maintaining engagement between the blocking tab and the locking tab.

14. The computer front bezel as described in claim 12, wherein an operating member is secured on the bezel body for sliding the sliding member on the bezel body to release the blocking tab from the locking tab.

15. The computer front bezel as described in claim 11, wherein a plurality of guiding blocks is formed on the bezel body, two rims respectively formed on opposite edges of the sliding member and slidably positioned between portions of the guiding blocks and the bezel body.

16. The computer front bezel as described in claim 11, wherein a damping member is secured on the bezel body and having a rotatable pinion, an arc toothed portion being formed on the holding member for engaging with the pinion of the damping member to have the holding being slidably pivoted.

17. A computer front bezel, comprising:
a bezel body comprising a plurality of walls any adjacent two of which are perpendicularly connected with each other to cooperatively define a space therebetween, one of the walls defining an opening therethrough;
a holding member defining a receiving space configured for receiving at least one electronic component therein, the holding member pivotably attached to the bezel body and capable of being pivoted between a closed position in which the holding member is received within the space of the bezel body and covers the opening to cause the receiving space of the holding member to be unaccessible from outside of the bezel body, and an open position in which the holding member is rotated out from the opening of the bezel body to allow the receiving space of the holding member to be accessible from outside of the bezel body, a locking member being formed on the holding member;
a sliding member slidably attached to the bezel body, a blocking member being formed on the sliding member configured for engaging with the locking member to retain the holding member in the closed position;
a first resilient member connected between the bezel body and the sliding member for urging the blocking member engaging with the locking member;
an operating member secured on the bezel body and being operatable from outside of the bezel body to drive the sliding member to slide to thereby disengage the blocking member from the locking member; and
a second resilient member connected between the bezel body and the holding member configured for driving the holding member to pivot from the closed position to the open position when the blocking member is disengaged from the locking member.

18. The computer front bezel as described in claim 17, further comprising a mounting member fixed in the space of the bezel body, wherein the walls of the bezel body comprises a front wall on which the opening is defined and a pair of side walls extending backward from opposite sides of the front wall, the mounting member comprises two side walls parallel to the side walls of the bezel body and a rear wall fixed with the front wall of the bezel body, and the holding member is pivotably connected to the side walls of the mounting member via pivot posts formed in one of the holding member and the mounting member being received in holes defined in the other one of the holding member and the mounting member.

19. The computer front bezel as described in claim 18, wherein the operating member is slidably mounted to one of the side walls of the bezel body in a first direction perpendicular to the one of the side walls, the sliding member is slidably mounted to an inner surface of the one of the side walls in a second direction parallel to the one of the side walls, the operating member engaging with the sliding member in such a manner that when the operating member is pushed in the first direction the sliding member is driven by the operating member to slide in the second direction to thereby disengage the blocking member from the locking member.

20. The computer front bezel as described in claim 18, wherein the second resilient member comprises a torsion spring with two ends, one end of the torsion spring being secured to the mounting member, and the other end of the torsion spring being mounted to one side of the holding member opposing the front wall of the bezel body.
